(19) United States
(12) Patent Application Publication
(10) Pub. No.: US 2010/0037819 A1
(43) Pub. Date: Feb. 18, 2010

(54) DEVICE FOR POSITIONING NANO MATERIALS

(75) Inventor: Youngtack SHIM, Seoul (KR)

Correspondence Address: KNOBBE MARTENS OLSON & BEAR LLP, 2040 MAIN STREET, FOURTEENTH FLOOR, IRVINE, CA, 92614, US

(73) Assignee: SNU R&DB Foundation, Seoul (KR)

(21) Appl. No.: 12/192,003

(22) Filed: Aug. 14, 2008

(51) Int. Cl. C23C 16/54

(52) U.S. Cl. 118/697; 118/715

(57) ABSTRACT

Techniques for positioning the nano-materials onto one or more targets are provided. In some embodiments, a device for positioning the nano-materials onto one or more targets may comprise a delivery line for delivering a gas from a gas supply, an applicator coupled to the delivery line and having a tip for ejecting the gas, the tip being adjustable so as to be oriented at a predetermined ejection angle with respect to said one or more targets, and an actuator coupled to the applicator for driving the applicator to move over said one or more targets and change the orientation of the tip.

The described technology generally relates to a device used in a semiconductor fabrication process, and more particularly to a device for positioning nano-materials on a target during a semiconductor fabrication process.

### BACKGROUND

With the advent of nano-technology, nano-materials are now applied in various fields of electronics, optics and material science due to their superior mechanical, chemical or electrical properties. For example, the nano-materials are widely used in micro devices such as integrated circuits, electrical connectors used in computer semiconductor chips, batteries, high-frequency antennas, scanning tunnel microscopes, atomic force microscopes and scanning probe microscopes.

However, there are certain drawbacks in applying the nano-materials to a semiconductor fabrication process. This is mainly because there is a lack of suitable mechanism for disposing the nano-materials in a target spot during the semiconductor fabrication process. In particular, the failure to implement a specific mechanism for positioning the nano-materials onto a chip severely deters the practical applications of various nano-materials. Thus, there is a clear need in the art for a device and method which can precisely position various nano-materials onto a chip during a semiconductor fabrication process.

### SUMMARY

A device for positioning nano-materials onto one or more targets is provided. In one embodiment, the device may comprise a delivery line for delivering a gas from a gas supply, an applicator coupled to the delivery line and including a tip for ejecting the gas, the tip being adjustable so as to be oriented at a predetermined ejection angle with respect to said one or more targets, and an actuator coupled to the applicator to cause the applicator to move over said targets and change the orientation of the tip.

This Summary is provided to introduce a selection of concepts in a simplified form that are further described below in the Detailed Description. The Summary is not intended to identify or essential features of the claimed subject matter, nor is it intended to be used to limit the scope of the claimed subject matter.

### BRIEF DESCRIPTION OF THE DRAWINGS

The forgoing and other features of the present disclosure will become more fully apparent from the following description and appended claims, taken in conjunction with the accompanying drawings. Note that these drawings depict only several embodiments in accordance with the disclosure and are, therefore, not to be considered limiting of its scope, the disclosure will be described with additional specificity and detail through use of the accompanying drawings in which:

FIG. 1 shows a schematic view of a fabrication equipment in accordance with one embodiment;

FIG. 2 shows a perspective view of a gas jet device for nano-materials in accordance with one embodiment;

FIG. 3 shows a cross-sectional view of a substrate prepared in accordance with one embodiment;

FIG. 4 shows a cross-sectional view of an insulator deposited on a substrate in accordance with one embodiment;

FIG. 5 shows a cross-sectional view of a groove formed by an insulator and substrate in accordance with one embodiment;

FIG. 6 shows a cross-sectional view illustrating a degassing step in accordance with one embodiment;

FIG. 7 shows a cross-sectional view illustrating a step in which a suspension of nano-materials is supplied in accordance with one embodiment;

FIGS. 8-12 show cross-sectional views illustrating how a gas stream is ejected toward a suspension of nano-materials in accordance with one embodiment;

FIG. 13 shows a cross-sectional view of remaining nano-materials after a gas stream is ejected in accordance with one embodiment;

FIG. 14 shows a cross-sectional view illustrating a drying step in accordance with one embodiment;

FIG. 15 shows a cross-sectional view of a conductor deposited in an insulator in accordance with one embodiment; and

FIG. 16 shows a cross-sectional view of a resultant structure after performing a removing step in accordance with one embodiment.

### DETAILED DESCRIPTION

It will be readily understood that the components of the present disclosure, as generally described and illustrated in the Figures herein, could be arranged and designed in a wide variety of different configurations. Thus, the following detailed description of the embodiments of apparatus and methods in accordance with the present disclosure, as represented in the Figures, is not intended to limit the scope of the present claims, but is merely representative of certain examples of presently contemplated embodiments in accordance with the present disclosure. The presently described embodiments will be best understood by reference to the drawings, wherein like parts are designated by like numerals throughout.

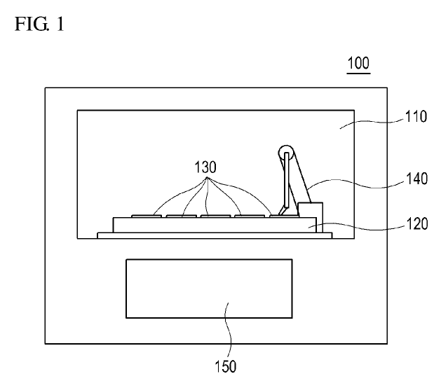

FIG. 1 shows an overall configuration of a fabrication equipment (“FAB equipment”) in accordance with one embodiment. In FIG. 1, conventional components of the FAB equipment are omitted for the simplicity of illustration. For example, such conventional components may include robot arms for manipulating the table or targets, gas nozzles and/or regulators for providing gases necessary for proper semiconductor fabrication, etc. In one embodiment, the FAB equipment 100 may comprise body and bottom sections.

The body section may be configured as a chamber 110 which is generally sealed so that the temperature and pressure therein can be controlled according to a desired pattern. As shown in FIG. 1, a table 120, on which one or more targets 130 such as silicon wafers are placed, may be disposed inside the chamber 110. A gas jet device 140 for positioning the nano-materials may be movably arranged so that the gas jet device 140 provides a gas stream to each target 130 on the table 120. That is, the gas jet device 140 may move over one or more targets 130.

The bottom section may include a control module 150 for controlling various operations of the equipment 100. In one embodiment, a suitable algorithm for controlling a moving velocity, incident angle of the gas jet device 140, ejection amount of the gas, etc., may be stored in advance in the control module 150. One of ordinary skill in the art would understand that the conventional operations conducted in the common semiconductor fabrication equipment, including regulating the temperature and pressure of the chamber 110, etc., may also be controlled by the control module.

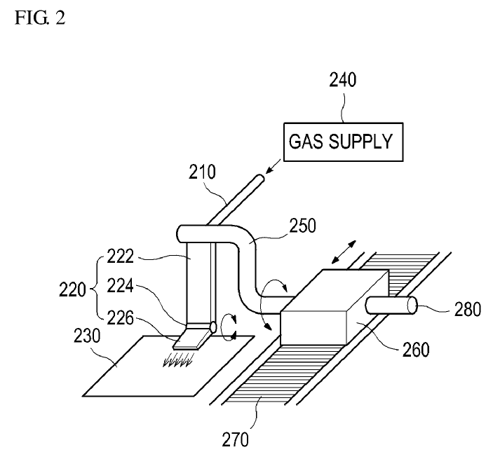

FIG. 2 shows a perspective view of a gas jet device 140 for positioning nano-materials on a target in accordance with one embodiment. In one embodiment, the gas jet device 140 may comprise a delivery line 210, an applicator 220, and an actuator 260. In one embodiment, the applicator 220 may include an intermediate line 222, a pivot 224 and a tip 226. The tip 226 of the applicator 220 may be arranged so that it can freely rotate about the pivot 224. With this structure, the applicator 220 may provide the gas stream to a target 230 from a suitable distance and a preset incident angle. Although the tip 226 is illustrated in FIG. 2 as being elongated and duckbill-shaped such that the gas stream can be efficiently ejected over a width thereof, the shape of the tip 226 is certainly not limited thereto. Rather, it should be appreciated that the tip 226 may have other shapes and sizes as long as the tip 226 can efficiently eject the gas stream to the target 230.

As shown in FIG. 2, the intermediate line 222 may be configured to accommodate the tip 226. Thus, the intermediate line 222 may have various designs according to the shapes of the tip 226. In some embodiments, the width of the intermediate line 222 may be wider or narrower compared to that of the tip 226 of the applicator 220. According to various embodiments, the intermediate line 222 may be made from either an inelastic or elastic material.

A gas may be supplied from a gas supply 240 toward the tip 226 of the applicator 220 through the delivery line 210 and the intermediate line 222. In one embodiment, the gas supply 240 may be configured as a pressurized gas storage which may be refilled or replaced after use. Alternatively, the gas supply 240 may be in the form of a gas pump which accommodates the gas in room or other low pressure, pressurizes the gas to a desired pressure and delivers the gas through the delivery line 210. Various types of gases including inert gas, air, etc. may be used as the gas supplied from the gas supply 240. For example, if the air is supplied from the gas supply 240, then a filter for removing impurities from the air may be additionally included. According to various embodiments, other known gases which are frequently used in a semiconductor fabrication process, MEMS, etc., may be used for the gas supply 240.

As shown in FIG. 2, the intermediate line 222 of the applicator 220 is coupled to an actuator 260 through a connection line 250. Although not shown in the figure, the actuator 260 includes a gear which fits into a track 270. As the actuator 260 moves its gear, the actuator 260 itself can translate over the track 270 at a desired speed. As the actuator 260 moves along the track 270, the tip 226 of the applicator 220 is laterally translated with regard to the target 230 while maintaining a distance from the tip 226 to the target 230. In addition, the actuator 260 may also rotate or tilt a central shaft 270 which then rotates or pivots the connection line 250 mechanically coupled thereto with respect to the target 230. As such, the actuator 260 may drive the applicator 220 in order to change its disposition and/or arrangement with respect to the target 230. The actuator 260 may also be arranged to move the applicator 220 to translate, rotate, pivot or tilt the applicator 220 in various scales. In one embodiment, the actuator 260 may manipulate the applicator 220 in a lower micron to an upper nano ranges. In another embodiment, the actuator 260 may manipulate the applicator 220 below the upper nano ranges. One of ordinary skill in the art would understand that other suitable technologies may be adopted for driving the applicator 220 to move along the table 120 in the above scales.

According to various embodiments, the gas jet device 140 may further comprise a control member (not shown). In such a case, the control member may be incorporated in the gas jet device 140 at various locations of the gas jet device 140. As one example, the control member may be incorporated in the actuator 260. In such a case, the control member may manipulate the movement of the actuator 260 according to a predetermined algorithm stored therein. In some embodiments, a moving velocity of the movement of the actuator 260, an incident angle of the gas jet device 140, an ejection amount of the gas, etc. may be controlled by the predetermined algorithm.

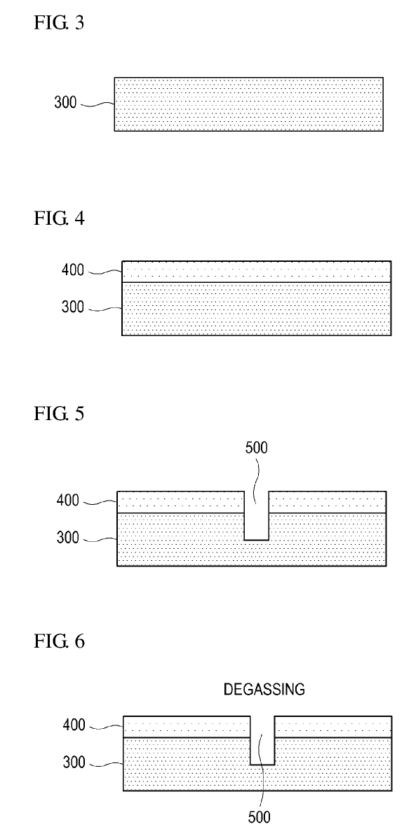

A semiconductor fabrication process is now explained. During said process, the gas jet device 140 is used for positioning the nano-materials on a target. FIGS. 3-16 show cross-sectional views illustrating a semiconductor fabrication process in accordance with one embodiment. Referring now to FIG. 3, the process may begin by preparing a substrate 300. The substrate 300 may include a silicon substrate, a silicon-on-insulator (SOI) substrate, a germanium substrate, a geranium-on-insulator (GOI) substrate, a silicon-geranium substrate and the like. That is, any conventional materials of desired mechanical integrity may be used as the substrate 300. The substrate 300 may be formed by using conventional forming and preparation techniques. In one embodiment, the substrate 3000 may be polished to provide a regular and flat surface.

Referring to FIG. 4, an insulator 400 is deposited over the substrate. The insulator 400 may be formed from conventional insulation materials and have a predetermined thickness. In one embodiment, a film of oxide such as silicon oxide (SiO₂) may be used as the insulator 400 where the silicon oxide is coated over the insulator 400 by approximately 750 nm. In another embodiment, the substrate 300 may be coated with a photoresist by using any of the various deposition techniques known in the art such as, but not limited to, spin coating.

Referring to FIG. 5, a groove 500 is formed through the insulator 400 and the substrate 300. The insulator 400 may be patterned or shaped using photolithography or other commonly known techniques to define a single vertical groove 500. Only one groove 500 is shown in FIG. 5 for illustrative purposes. However, it should be noted herein that two or more grooves may be formed according to various embodiments. Further, as shown in FIG. 5, the groove 500 extends not only into the insulator 400 but also into the substrate 300.

FIG. 6 illustrates a degassing step in which any remnant air or gas on the substrate 300 and insulator 400 may be removed. The degassing step may be conducted for a period of time which is sufficient to remove the remnant air and gas. The pressure under which the degassing step is conducted may be regulated in order to effectively remove the remnant air and gas. Depending on the need, the degassing step may be repeated more than once.

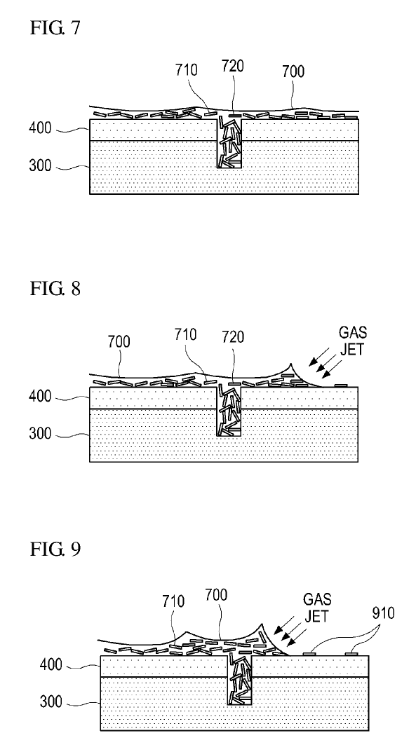

Referring to FIG. 7, a suspension of nano-materials is supplied on top of the insulator 400. In one embodiment, carbon nanotubes, carbon nanowire, etc. may be used as nano-materials. The suspension 700 of nano-materials may be viscous enough so as not to cause separation of the nano-materials therefrom. The nano-materials may be supplied in other forms including emulsion, solution or liquid mixture according to various embodiments. The shape and size of the nano-materials used in the semiconductor fabrication process may vary depending on the application. For example, the nano-materials included in the suspension 700 have elongated shapes and are appropriately sized so as to be capable of being accommodated in the groove 500.

As shown in FIG. 7, some of the nano-materials may be trapped in the groove 500. The amount of nano-materials trapped in the groove 500 depends on numerous factors such as a dimension of the groove 500, shape and size of the nano materials, curvature of the nano-materials, etc. Since the nano-materials do not fall into the groove 500 in a controlled manner at this stage, there may be some nano-materials 720 which fall across a top of the groove 500 and prevent other nano-materials from entering the groove 500.

Referring to FIGS. 8-12, a gas jet is ejected toward a suspension of nano-materials in accordance with one embodiment. The ejection of the gas jet may be advantageous in removing the above-mentioned nano materials 720 from the top of the groove 500. The ejection of the gas jet may be performed by the gas jet device 140. As shown in FIGS. 8-12, the gas jet may be ejected, for example, from the right side to the left side, although the ejection direction and angle may be certainly not limited thereto.

For the ejection of the gas jet from the right side to the left side, the gas jet device 140 may move more to the left by the actuator 200. As the gas jet device 140 moves more to the left side, the gas jet moves the suspension 700 including the nano-materials more to the left side. Such movement of the suspension 700 has a desired effect upon the nano-materials disposed around the top or entrance of the groove 500. For example, due to the movement of the suspension 700, the misaligned nano-materials 720 around the top or entrance of the groove 500 may be moved away from the top or entrance of the groove 500, thereby allowing other nano-materials to be inserted into the groove 500. In addition, the suspension 700 is pressurized by the gas jet ejection. Thus, hydraulic pressure may be generated. The generated hydraulic pressure enables the nano-materials loosely packed inside the groove 500 to move deeper into the groove as well as the nano-materials disposed near the top of the groove 500 to enter the groove 500, thereby trapping more nano-materials in the groove 500. That is, due to the gas jet ejection, a larger amount of nano-materials can be deposited in the groove 500 than otherwise. It is appreciated that the gas jet may also facilitate alignment of the nano-materials inside the groove 500. That is, by adjusting the gas jet to be perpendicular to the length direction of the groove 500, the nano-materials which are aligned with the groove 500 (which is, therefore, aligned normal to the gas jet) would have more tendency to fall into the groove 500 than those which are not aligned with the groove. In this context, the gas jet device not only increases the amount of the nano-materials trapped in the groove 500 but also facilitates the nano-materials to be aligned in the groove 500 along the length direction of the groove 500.

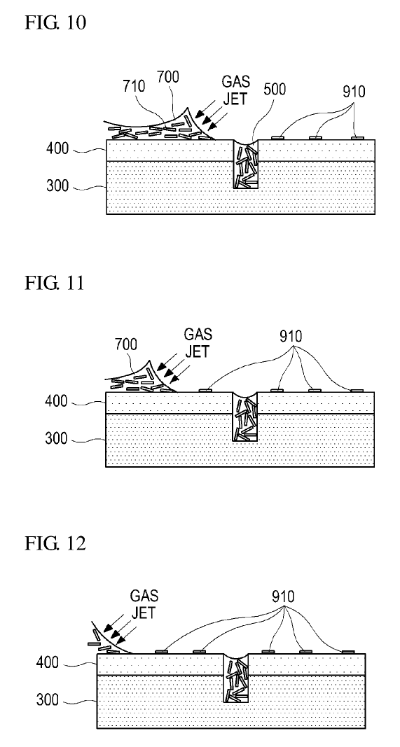

Along with the movement of the gas jet device 140, an angle at which the gas jet is ejected from the gas jet device 140 may vary. For example, if the ejection angle set when the gas jet ejection approaches the groove 500 (FIG. 9) is still maintained when the gas jet device 140 passes the groove 500 (FIG. 10), the gas jet ejection may blow out the nano-materials, thereby trapping a less amount of nano-materials inside the groove 500. Thus, according to the movement of the gas jet device 140, an ejection or incidence angle at which the gas jet is ejected may be regulated so that a greatest possible amount of nano-materials may be trapped in the groove 500. The optimum ejection angle at each stage depends on various factors, e.g., a width and depth of the groove 500, a length of the nano-material, a concentration of the nano-materials in the suspension, a viscosity of the suspension, a desired amount of nano-materials to be trapped into a unit volume of the groove 500, etc.

In addition to the incidence angle, a volumetric flow rate as well as an ejection pressure may also be important factors in depositing the nano-materials in the groove 500. One of ordinary skill in the art may determine the incidence angle, gas flow rate and gas pressure by considering concentration of the suspension 700, dynamic and kinematic viscosity of the suspension 700, number of sweepings of the gas jet process, etc. As mentioned above, the algorithm and various parameters thereof for controlling the factors such as incidence angle of the gas jet or gas jet device, gas flow rate, gas pressure, etc. may be stored in advance in the control module 150.

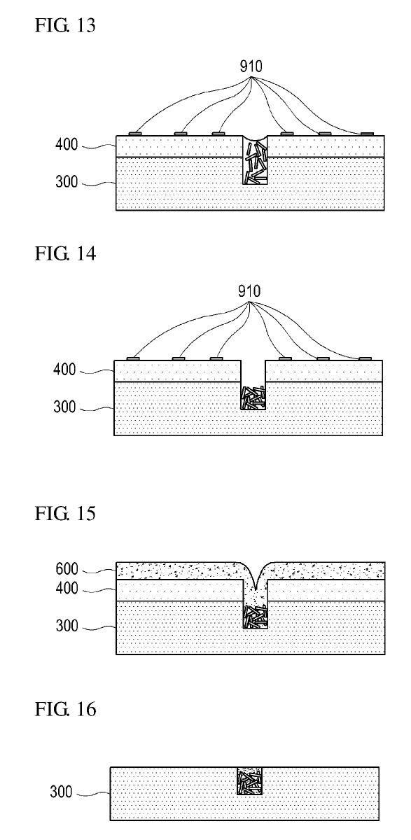

Further, despite such ejection of the gas jet, some of the nano-materials 910 may exist on the insulator 400 while not falling into the groove 500 or moving to the left side of the insulator 400 as shown in FIG. 13. The remaining nano-materials may cause malfunction of a device by forming an unwanted electric circuit. Thus, it is more desirable to remove such remaining nano-materials. As such, as shown in FIG. 14, a drying step may be conducted to evaporate the remaining suspension from a surface of the insulator 400 and groove 500. In accordance with one embodiment, once the drying step is completed, a conductor 600 may be deposited over the insulator 400 and groove 500 as shown in FIG. 15. Then, the conductor 600 and the insulator 400 may be removed by suitable methods including photolithography, etching, etc., as shown in FIG. 16. As a result, an elongated nano structure can be fabricated, in which the amount of the nano-materials per unit volume of the structure can be maximized by employing the gas jet device.

One of ordinary skill in the art will appreciate that an additional process such as patterning, assembling, etc. may be conducted upon the manufacture structure shown in FIG. 16.

In light of the present disclosure, those skilled in the art will appreciate that the apparatus and methods described herein may be implemented in hardware, software, firmware, middleware or combinations thereof and utilized in systems, subsystems, components or sub-components thereof. For example, a method implemented in software may include computer code to perform the operations of the method. This computer code may be stored in a machine-readable medium, such as a processor-readable medium or a computer program product, or transmitted as a computer data signal embodied in a carrier wave, or a signal modulated by a carrier, over a transmission medium or communication link. The machine-readable medium or processor-readable medium may include any medium capable of storing or transferring information in a form readable and executable by a machine (e.g., by a processor, computer, etc.).

While the present disclosure has been shown and described with respect to specific embodiments, those skilled in the art will recognize that various changes and modifications may be made without departing from the spirit and scope of the invention as defined in the appended claims.

What is claimed is:

1. A gas jet device for fabrication equipment defining a chamber in which a fabrication is performed on at least one target disposed inside the chamber, wherein the device receives a gas from one end and discharges the gas through another end for the fabrication, the device comprising:
at least one applicator disposed in the chamber and being configured to be disposed in one of a plurality of distances from the target and in one of a plurality of incident angles with respect to the target, the at least one applicator being configured to receive the gas and eject the gas onto the target from one of said distances and in one of said angles;
at least one delivery line in fluid communication with the at least one applicator and being configured to supply the gas to the at least one applicator; and
at least one actuator operatively coupled with the applicator and being configured to move the at least one applicator from one to another of said distances, the at least one actuator further being configured to manipulate the at least one applicator to eject the gas from one to another of said angles,
wherein the device is configured to manipulate the distances and angles such that the gas flows to the target in a preset velocity and a preset flow rate from one of the distances and in one of the angles.

2. The device of claim 1, wherein the delivery line is supplied with the gas from a gas supply.

3. The device of claim 1, wherein the gas includes inert gas and air.

4. The device of claim 1, wherein the applicator comprises:
a tip configured to eject the gas;
a pivot to which the tip is rotatably mounted; and
an intermediate line positioned between the pivot and the delivery line.

5. The device of claim 4, wherein the angle is changed by the rotation of the tip.

6. The device of claim 1, wherein the actuator includes a gear and the movement of the actuator is caused by a movement of the gear.

7. A gas jet device for fabrication equipment defining a chamber in which a fabrication is performed on at least one target defining at least one groove and being disposed in the chamber, wherein the fabrication includes positioning a nano material in the groove and wherein the device receives gas from one end and discharges the gas through another end for the positioning, the device comprising:
at least one applicator disposed in the chamber and being configured to receive the gas, the at least one application further being configured to eject the gas onto the target from one of a plurality of distances and in one of a plurality of angles;
at least one delivery line in fluid communication with the at least one applicator and being configured to supply the gas to the at least one applicator;
at least one actuator operatively coupled with the at least one applicator and being configured to generate a movement of at least one of translation of at least a portion of the applicator in a nano scale, rotation thereof, pivoting thereof, and tilting thereof with respect to the target; and
at least one control member operatively coupled with the at least one actuator and being configured to manipulate the movement of the at least one actuator,
wherein the device is configured to manipulate a distance between the target and the at least one applicator and an incident angle of the gas onto the target such that the gas flows to the target in a preset velocity and a preset flow rate from the distance and in the angle.

8. The device of claim 7, wherein the delivery line is supplied with the gas from a gas supply.

9. The device of claim 7, wherein the gas includes inert gas and air.

10. The device of claim 7, wherein the applicator comprises:
a tip configured to eject the gas;
a pivot to which the tip is rotatably mounted; and
an intermediate line positioned between the pivot and the delivery line.

11. The device of claim 10, wherein the angle is changed by the rotation of the tip.

12. The device of claim 7, wherein the actuator includes a gear and the movement of the actuator is caused by a movement of the gear.

13. A device for positioning nano-materials onto one or more targets, comprising:
a delivery line for delivering a gas;
an applicator coupled to the delivery line and having a tip for ejecting the gas, said tip being adjustable so as to be oriented at a predetermined ejection angle with respect to said one or more targets; and
an actuator coupled to the applicator and being configured to drive the applicator to move over said one or more targets and change the orientation of the tip.

14. The device of claim 13, wherein the delivery line is supplied with the gas from a gas supply.

15. The device of claim 14, wherein the gas supply is any one of a pressurized gas storage and gas pump.

16. The device of claim 13, wherein the gas includes inert gas and air.

17. The device of claim 16, further comprising a filter for removing impurities from the air if the air is supplied from the gas supply.

18. The device of claim 13, wherein the applicator comprises:
a pivot to which the tip is rotatably mounted; and
an intermediate line positioned between the pivot and the delivery line.

19. The device of claim 18, wherein the ejection angle is changed by the rotation of the tip.

20. The device of claim 13, wherein the ejection angle is controlled by a predetermined algorithm.

21. The device of claim 13, wherein the tip is duck-bill shaped so that the gas is ejected through a width thereof

22. The device of claim 18, wherein the intermediate line is made from any one of an inelastic material and elastic material.

23. The device of claim 13, wherein the actuator is connected to the applicator through a connection line.

24. The device of claim 13, wherein the actuator includes a gear and the movement of the actuator is caused by a movement of the gear.

25. The device of claim 24, wherein the actuator includes a control member and a moving velocity of the actuator is controlled by a predetermined algorithm stored in the control member.

26. The device of claim 18, wherein the intermediate line may be configured to accommodate the tip.

27. The device of claim 13, wherein the nano-materials include carbon nanotubes and carbon nanowire.
